(19) United States
(12) Patent Application Publication
(10) Pub. No.: US 2025/0322898 A1
(43) Pub. Date: Oct. 16, 2025

(54) MEMORY DEVICE HAVING CONDUCTIVE PLATE SHORT REPAIR

(71) Applicant: Micron Technology, Inc., Boise, ID (US)

(72) Inventors: Makoto Kitagawa, Folsom, CA (US); Daniele Vimercati, El Dorado Hills, CA (US)

(21) Appl. No.: 19/174,239

(22) Filed: Apr. 9, 2025

Related U.S. Application Data
(60) Provisional application No. 63/632,297, filed on Apr. 10, 2024.

(51) Int. Cl. G11C 29/44; G11C 11/22

(52) U.S. Cl. CPC G11C 29/4401; G11C 11/221; G11C 11/2257; G11C 11/2259; G11C 11/2273

(57) ABSTRACT

Some embodiments include apparatuses and methods of operating the apparatuses. One of the apparatuses includes conductive plates adjacent each other; memory cells associated with the conductive plates; drivers coupled to the conductive plates such that one of the drivers is associated with one of the conductive plates; and a short coupled between a first conductive plate of the conductive plate and a second conductive plate of the conductive plates.

### PRIORITY APPLICATION

This application claims the benefit of priority to U.S. Provisional Application Ser. No. 63/632,297, filed Apr. 10, 2024, which is incorporated herein by reference in its entirety.

### BACKGROUND

Many electronic devices (e.g., cellular phones and computers) have a memory device used to store information. Some memory devices have conductive plates to provide voltage to part of the memory cells. During fabrication of the memory device, a short (e.g., circuit defect) may occur in part of the memory device including the conductive plates. Such a short may cause the memory device to be discarded, thereby reducing yield and increasing cost associated with fabrication of such memory devices.

### BRIEF DESCRIPTION OF THE DRAWINGS

FIG. 1 shows an apparatus in the form of a memory device, according to some embodiments described herein.

FIG. 2A shows a memory device including conductive plates and associated memory cells, according to some embodiments described herein.

FIG. 2B shows a portion of the memory device of FIG. 2A including a memory cell, a driver (cell plate driver), and a transistor, according to some embodiments described herein.

FIG. 3 shows a memory device including conductive plate groups (groups of conductive plates), according to some embodiments described herein.

FIG. 4 shows a memory device including conductive plate groups and multiplexers, according to some embodiments described herein.

FIG. 5 is a flowchart of an example method for operating a memory device, according to some embodiments described herein.

FIG. 6 shows an apparatus in the form of a system, according to some embodiments described herein.

### DETAILED DESCRIPTION

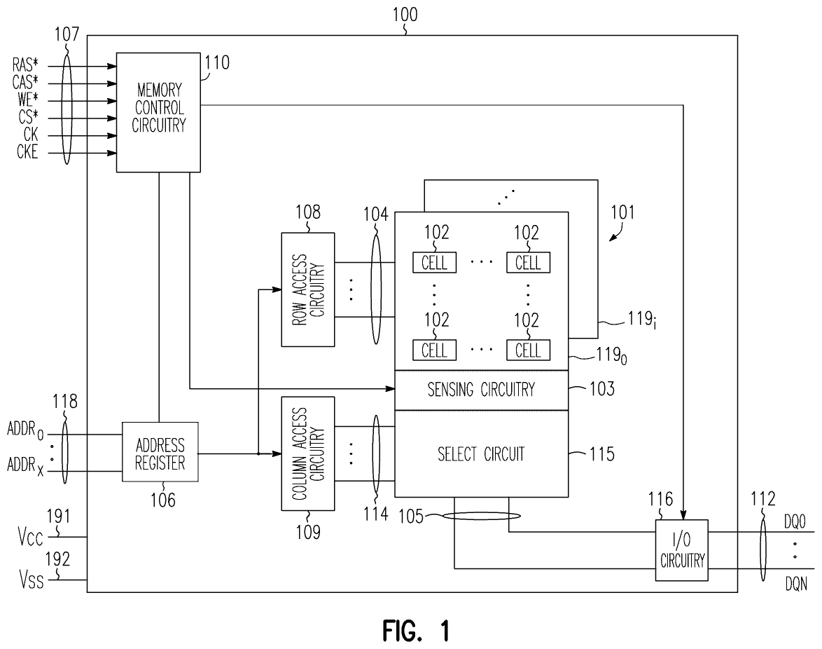

The techniques described herein involve a memory device having conductive plates and configuration to repair a short that may occur between the conductive plates. In an example, the techniques described herein provide ways to use at least part of a damaged portion of the memory device due to such a short. The memory device also includes a redundant (spare) memory portion to replace (e.g., repair) the damaged portion. The techniques described herein can improve yield and reduce cost associated with fabrication of the described memory device. Other improvements and benefits of the described techniques are further discussed below with reference to FIG. 1 through FIG. 6.

FIG. 1 shows a block diagram of an apparatus in the form of a memory device 100 including volatile memory cells, according to some embodiments described herein. Memory device 100 includes a memory array (or memory arrays) 101, which can contain memory cells 102. Memory cells 102 can be organized into banks 119₀ through 119ᵢ, each can include a number of memory cells 102. Memory device 100 can include a volatile memory device or a non-volatile memory device. An example of memory device 100 includes a dynamic random-access memory (DRAM) device, a ferroelectric random-access memory (FeRAM) device, or other types of random-access memory (RAM) devices.

In an example, information stored in memory cells 102 of memory device 100 may be lost (e.g., invalid) if supply power (e.g., supply voltage Vcc) is disconnected from memory device 100. In another example, memory device 100 may retain the value of information stored in memory cells 102 even if supply power is disconnected from memory device 100.

In this description, supply voltage Vcc is referred to as representing some voltage levels; however, they are not limited to a supply voltage (e.g., Vcc) of the memory device (e.g., memory device 100). For example, if the memory device (e.g., memory device 100) has an internal voltage generator (not shown in FIG. 1) that generates an internal voltage based on supply voltage Vcc, such an internal voltage may be used instead of supply voltage Vcc.

In a physical structure of memory device 100, each of memory cells 102 can include a transistor (e.g., an access transistor) and a storage element. The storage element can include a capacitor or other storage elements different from a capacitor. Each of memory cells 102 can be configured to store information that can represent at most one bit (e.g., a single bit having a binary 0 (“0”) or a binary 1 (“1”), or more than one bit (e.g., multiple bits having a combination of at least two binary bits).

As shown in FIG. 1, memory device 100 can include access lines 104 (e.g., “word lines”) and data lines 105. Data lines 105 can include digit lines (also called bit lines). Memory device 100 can use signals (e.g., word line signals) on access lines 104 to access memory cells 102 and data lines 105 to provide information (e.g., data) to be stored in (e.g., to be written to or programed in) or read (e.g., sensed) from memory cells 102.

Memory device 100 can include an address register 106 to receive address information in the form of signals (e.g., row address signals and column address signals) ADDR_{R} through ADDR_{X} on conductive lines (e.g., address lines) of a bus (e.g., address bus) 118. Information ADDR is associated with addresses of memory cells 102 of memory device 100. Memory device 100 can include row access circuitry 108 (e.g., X-decoder) and column access circuitry 109 (e.g., Y-decoder) that can operate to decode address information ADDR from address register 106. Based on decoded address information, memory device 100 can determine which memory cells 102 are to be accessed during a memory operation. Memory device 100 can perform a write operation to store information in memory cells 102, and a read operation to read (e.g., sense) information (e.g., previously stored information) in memory cells 102.

Memory device 100 can receive a supply voltage, including supply voltages Vcc and Vss, on lines 191 and 192, respectively. Supply voltage Vss can operate at a ground potential (e.g., having a value of approximately zero volts). Supply voltage Vcc can include an external voltage supplied to memory device 100 from an external power source such as a battery or an alternating current to direct current (AC-DC) converter circuitry.

As shown in FIG. 1, memory device 100 can include a memory control circuitry 110, which includes components (e.g., software, firmware, hardware, or any combination of these components) to control memory operations (e.g., read and write operations) of memory device 100 based on control signals on conductive lines (e.g., control lines) of a bus (e.g., command bus) 107 of memory device 100. Examples of signals on the conductive lines of bus 107 include a row access strobe signal RAS*, a column access strobe signal CAS*, a write-enable signal WE*, a chip select signal CS*, a clock signal CK, and a clock-enable signal CKE. These signals can be part of signals provided to a DRAM device or a FeRAM (e.g., memory device 100). Different combinations of these signals can form different commands provided memory device 100. Examples of commands on the conductive lines of bus 107 (e.g., provided to memory device 100 from a memory controller) include a read command, a write command, and other commands associated with a memory device (e.g., a DRAM device or a FeRAM device).

As shown in FIG. 1, memory device 100 can include conductive lines (e.g., global data lines) of a bus (e.g., data bus) 112 that can carry signals DQ0 through DQN. The conductive lines of bus 112 can be part of a data bus of memory device 100. In a read operation, the value (e.g., “0” or “1”) of information (read from memory cells 102) provided to the conductive lines of bus 112 (in the form of signals DQ0 through DQN) can be based on the values of the signals on data lines 105. In a write operation, the value (e.g., “0” or “1”) of information provided to data lines 105 (to be stored in memory cells 102) can be based on the values of signals DQ0 through DQN on the conductive lines of bus 112.

Memory device 100 can include sensing circuitry 103, select circuitry 115, and input/output (I/O) circuitry 116. Column access circuitry 109 can selectively activate signals on lines (e.g., select lines) based on address signals ADDR. Select circuitry 115 can respond to the signals on lines 114 to select signals on data lines 105. The signals on data lines 105 can represent the values of information to be stored in memory cells 102 (e.g., during a write operation) or the values of information read (e.g., sensed) from memory cells 102 (e.g., during a read operation).

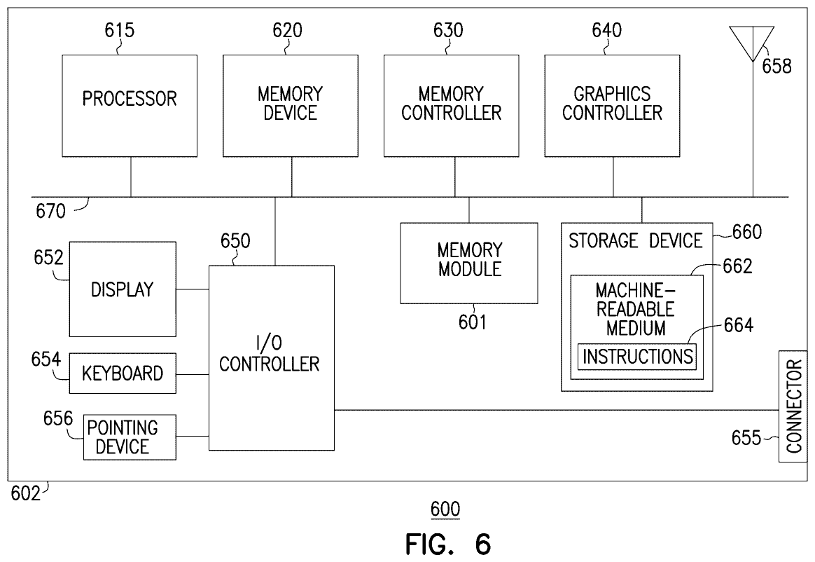

I/O circuitry 116 can operate to provide information read from memory cells 102 to the conductive lines of bus 112 (e.g., during a read operation) and to provide information from the conductive lines of bus 112 (e.g., provided by an external device) to data lines 105 to be stored in memory cells 102 (e.g., during a write operation). The conductive lines of bus 112 can include nodes within memory device 100 or pins (or solder balls) on a package where memory device 100 can reside. Other devices external to memory device 100 can communicate with memory device 100 through conductive buses 107, 112, and 118. Examples of the other external to memory device 100 can include a hardware memory controller (e.g., memory controller 630 (FIG. 6) or a hardware processor (e.g., processor 615 of FIG. 6).

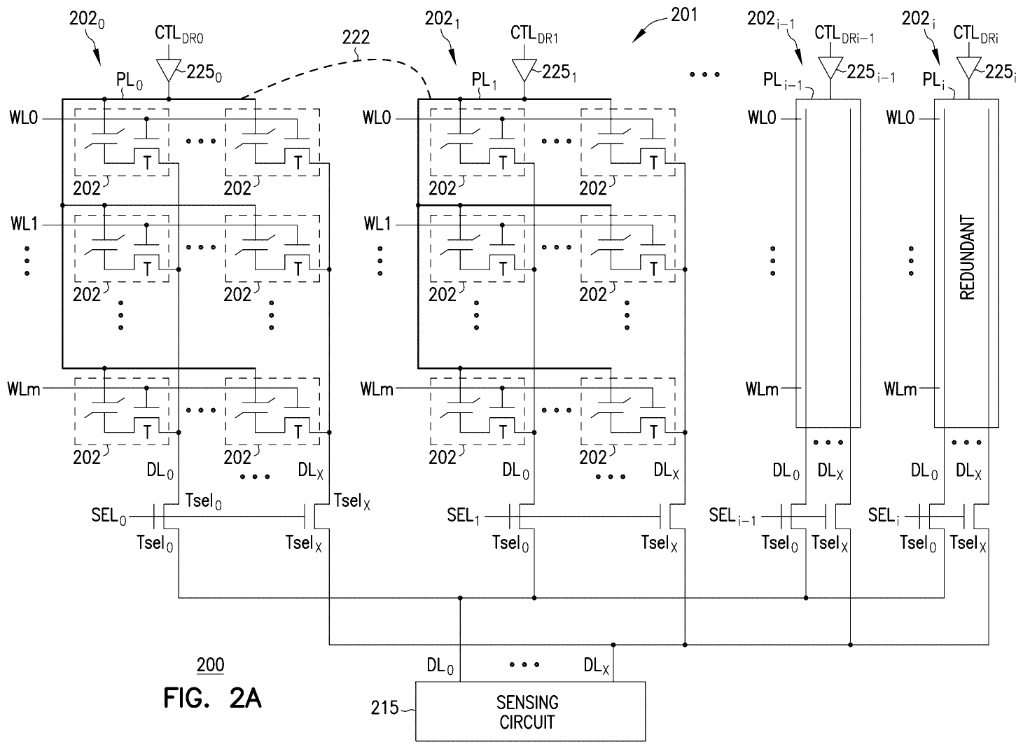

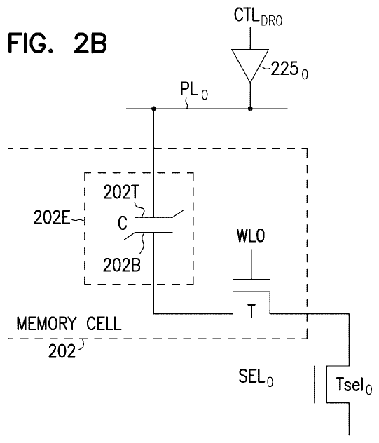

Memory device 100 may include other components, which are not shown in FIG. 1 so as not to obscure the example embodiments described herein. At least a portion of memory device 100 and operations of memory device 100 can include structures and operations similar to or the same as any of the memory devices described below with reference to FIG. 2A through FIG. 6.

FIG. 2A shows a portion of a memory device 200 including conductive plates PL₀ through PLᵢ and associated memory cells 202, according to some embodiments described herein. Memory device 200 can correspond to memory device 100 of FIG. 1. For example, memory device 200 can include a memory array (or memory arrays) 201 can form part of (or can correspond to) memory array 101 of FIG. 1.

As shown in FIG. 2A, memory device 200 can include conductive plates PL₀ through PLᵢ adjacent each other, memory cells 202 organized (e.g., formed) in memory cell groups 202₀ through 202ᵢ, and data lines (e.g., digit lines or bit lines) d0x and access lines (e.g., word lines) WL₀ through WLm associated with a respective conductive plate and a respective memory cell group. Each of data lines DL₀ through DL_{X} and each of access lines WL₀ through WLm can include (can be formed from) a conductive material (e.g., metal or other conductive materials). Each of conductive plates PL₀ through PLᵢ can include a conductive material (e.g., metal or other conductive materials). As shown in FIG. 2A, each conductive plate (among conductive plates PL₀ through PLᵢ) is associated with memory cells 202 of a memory cell group (among in memory cell groups 202₀ through 202ᵢ). For simplicity, details of memory cell groups 202ᵢ₋₁ and 202ᵢ are not shown in FIG. 2A.

In this description, a conductive plate (e.g., conductive plate PL₀) can also be called a cell plate (e.g., cell plate PL₀) or a memory cell plate (e.g., memory cell plate PL₀). Conductive plates PL₀ through PLᵢ are separated from each other. A conductive plate associated with a particular memory cell group (one of memory cell groups 202₀ through 202ᵢ) can be shared by (e.g., can be a common conductive plate of) memory cells 202 of that particular memory cell group.

For simplicity, FIG. 2A shows each of conductive plates PLᵢ₋₁ and PLᵢ as a box. However, each of conductive plates PLᵢ₋₁ and PL can be associated with circuit elements (e.g., memory cells, data lines, and access lines) like other conductive plates (e.g., conductive plates PL₀ and PL₁) of memory device 200.

FIG. 2A shows an example where access lines WL₀ through WLm associated with a memory cell group (a group of memory cells 202) can be separated from access lines WL₀ through WLm associated with another memory cell group (another group of memory cells 202). Alternatively, access lines WL₀ through WLm can be shared by two or more memory cell groups.

Memory device 200 can include a sensing circuit 215 and transistors (e.g., column select transistors) Tsel₀ through Tsel_{X} coupled between sensing circuit 215 and data lines DL₀ through DL_{X} associated with memory cells 202 (e.g., columns of memory cells 202) of a respective memory cell group. Each of data lines DL₀ through DL_{X} can include a conductive material (e.g., metal or other conductive materials). Transistors Tsel₀ through Tsel_{X} can be controlled (e.g., turned on or turned off) by corresponding signals (e.g., select signals) SEL₀ through SELᵢ. Memory cell groups 202₀ through 202ᵢ and associated conductive plates PL₀ through PLᵢ can share sensing circuit 215.

Transistors Tsel₀ through Tsel_{X} associated with a respective memory cell group can be called a transistor group. FIG. 2A shows an example of four transistor groups (each transistor group includes transistors Tsel₀ through Tsel_{X}). Data lines DL₀ through DL_{X} associated with a respective memory cell group can be called a data line group. FIG. 2A shows an example of four data line groups (each data line group includes data lines DL₀ through DL_{X}).

In a memory operation (e.g., a read operation), transistors Tsel₀ through Tsel_{X} can be turned on one transistor group at a time. This allows data lines DU through DL_{X} to couple to sensing circuit 215 one data line group at a time. When a data line group (e.g., data lines DL₀ through DL_{X} associated with memory cell group 202₀) is coupled to sensing circuit 215, the other data line groups (e.g., data lines DL₀ through DL_{X} associated with memory cell groups 202₁ through 202ᵢ) are decoupled from sensing circuit 215. Memory control circuitry of memory device 200 (e.g., similar to memory control circuitry 110 of FIG. 1) can be configured to selectively couple a data line group to sensing circuit 215 and decouple a data line group from sensing circuit 215.

As shown in FIG. 2A, memory device 200 can include drivers (driver circuits) 225₀ through 225ᵢ coupled to respective conductive plates PL₀ through PLᵢ in a one-to-one configuration (one-to-one relationship). In this one-to-one configuration, a driver (e.g., driver 225₀) coupled to a respective conductive plate (e.g., conductive plate PL0) is not shared with (is not coupled to) another conductive plate (or other conductive plates) of memory device 200. For example, as shown in FIG. 2A, driver 225₀ is coupled to conductive plate PL₀ and is not coupled to (is not shared with conductive plates PL₁ through PLᵢ. Thus, driver 225₀ can be used to apply a voltage to conductive plate PL₀ and not used to apply a voltage to other conductive plates PL₁ through PLᵢ. As described in more detail below, the one-to-one configuration of driver 225₀ through 225ᵢ and conductive plates PL₀ through PLᵢ allows memory device 200 to properly operate in a memory operation (e.g., read operation) in spite of a short that may occur in conductive plates PL₀ through PLᵢ.

In FIG. 2A, each of driver 225₀ through 225ᵢ can be activated (e.g., turned on) or deactivated (e.g., turned off) by a respective signal among signals (e.g., control signals) CTL_{DR0} through CTL_{DRi}. Drivers 225₀ through 225ᵢ can be separately activated (e.g., turned on) or deactivated (e.g., turned off) depending on whether a voltage is to be applied to a respective conductive plate. Memory control circuitry of memory device 200 (e.g., similar to memory control circuitry 110 of FIG. 1) can be configured to selectively activate or deactivate drivers 225.

A conductive plate (among conductive plates PL₀ through PLᵢ) can be applied with a voltage when a corresponding driver is turned on. For example, conductive plate PL₀ can be applied with a voltage (e.g., a positive voltage) when driver 225₀ is turned on. In another example, conductive plate PL1 can be applied with a voltage (e.g., a positive voltage) when driver 225₁ is turned on.

A conductive plate (among conductive plates PL₀ through PLᵢ) can be placed in a float condition (e.g., can be floated) during a memory operation when a corresponding driver is turned off. In a float condition, a conductive plate is neither coupled to a voltage source (e.g., voltage Vcc) nor ground connection (e.g., voltage Vss) through the corresponding driver (e.g., through a transistor (not shown) included in the corresponding driver). For example, during a memory operation of memory device 200, conductive plate PL1 can be placed in a float condition (can be floated) by deactivating (e.g., not turning on) driver 225₁. In this example, conductive plate PL₁ is not coupled to a voltage source (e.g., a positive voltage) or a ground connection (e.g., voltage Vss) when driver 225₀ is turned off.

As shown in FIG. 2A, each memory cell 202 can include a transistor (e.g., a row access transistor) T and a memory element 202E (labeled in FIG. 2B). For simplicity, FIG. 2A omits labels (e.g., 202E) of the memory element of each memory cell 202. A conductive plate associated with a particular memory cell group can form part of the memory elements of the memory cells of that particular memory cell group. For example, conductive plate PL₀ can form part of the memory elements of the memory cells 202 of memory cell group 202₀. In another example, conductive plate PL₁ can form part of the memory elements of the memory cells 202 of memory cell group 202₁.

FIG. 2B shows a portion of memory device 200 of FIG. 2A including memory cell 202, driver 225₀, and transistor Tsel₀, according to some embodiments described herein. As shown in FIG. 2B, memory cell 202 can include a memory element 202E coupled to conductive plate PL₀. Memory element 202E can include a plate (e.g., top plate) 202T, a plate (e.g., bottom plate) 202B, a material (e.g., insulating material, not shown) between plates 202T and 202B. Plate 202T can be coupled to (e.g., can be part of) conductive plate PL₀. Plate 202B can be coupled to a terminal (e.g., source or drain) of transistor T. Transistor T can have a terminal (e.g., drain or source) coupled to data line DL₀ through transistor SEL0.

Plates 202T and 202B and the material between plates 202T and 202B can form a capacitor C of memory element 202E of memory cell 202. Conductive plate PL₀ can form part of plate 202 of memory element 202E. In an example, the material between plates 202T and 202B of capacitor C can include a ferroelectric material, such that capacitor C is a ferroelectric capacitor. Thus, in an example, memory cell 202 is a ferroelectric memory cell (e.g., FeRAM memory cell) and memory device 200 is a FeRAM device. The FeRAM device (e.g., memory device 200) may have similar device architectures as a volatile memory device (e.g., a DRAM). However, the FeRAM device may have non-volatile properties due to the use of a ferroelectric capacitor (e.g., capacitor C of memory cell 202) to store information. Thus, an FeRAM device (e.g., memory device 200) may have improved performance compared to other non-volatile and volatile memory devices.

In FIG. 2B, memory element 202E can be configured to store information by charging or discharging capacitor C. Capacitor C can be charged or discharged to store different states to reflect different values (e.g., digital values) of information to be stored in memory cell 202. Memory cell 202 can be configured to store one bit (a single bit) of information or more than one bit of information.

In an example where capacitor C is a ferroelectric capacitor, information can be stored in memory cell 202 by applying a voltage across capacitor C in a write operation. In a write operation, transistors T and Tsel₀ can be turned on to access memory cell 202 and couple plate 202B of capacitor C to data line DL₀. The value of the voltage across capacitor C can be selected (to reflect the value of information to be stored in memory cell 202) by controlling the voltage on conductive plate PL₀ and the voltage on data line DL₀. Driver 225₀ can be activated (e.g., turned on) to apply a voltage to plate 202T through conductive plate PL₀. In an example write operation (e.g., to store logic “0” in memory cell 202), conductive plate PL₀ can be applied with a higher voltage (e.g., positive voltage) and data line DL₀ can be applied with a lower voltage (e.g., ground potential). In another example write operation (e.g., to store logic “1” in memory cell 202), conductive plate PL₀ can be applied with a lower voltage (e.g., ground potential) and data line DL₀ can be applied with a higher voltage (e.g., positive voltage).

A read operation can be performed to read information (previously stored information) from memory cell 202. In a read operation, transistors T and Tsel₀ can be turned on to access memory cell 202. Driver 225₀ can be activated to apply a voltage to conductive plate PL₀, thereby applying the voltage to plate 202T (which is coupled to conductive plate PL₀). Depending on the state (stored state) of capacitor C, a signal may be produced on data line DL₀. Sensing circuit 215 (e.g., a sense amplifier of sensing circuit 215) of FIG. 2A can operate to compare the signal (e.g., voltage) on data line DL₀ with a reference signal (e.g., a reference voltage, not shown). The result of the comparison can be used to determine the value (e.g., logic “0” or logic “1”) of information stored in memory cell 202. For example, the value of information stored in memory cell 202 is determined to be a logic “1” if the voltage on data line DL₀ is greater than the reference voltage. In another example, the value of information stored in memory cell 202 is determined to be a logic “0” if the voltage on data line DL₀ is less than the reference voltage.

In FIG. 2A, other memory cells 202 of memory array 201 can operate in ways similar to or the same as memory cell 202 described above with reference to FIG. 2B. For example, in FIG. 2A, in a write operation to store information in memory cells 202 associated with access line WL0 of memory cell group 202₀, access line WL0 and data lines DL₀ through DL_{X} associated with memory cell group 202₀ can be activated to access (e.g., to select) memory cells 202 associated with access line WL0 of memory cell group 202₀. Transistors T of memory cells 202 associated with access line WL0 of memory cell group 202₀ can be turned on when access line WL0 of memory cell group 202₀ is activated (selected). Transistors Tsel₀ through Tsel_{X} of memory cell group 202₀ can be turned on to activate data lines DL₀ through DL_{X} of memory cell group 202₀ and couple them to sensing circuit 215.

Driver 225₀ can be activated to apply a voltage to conductive plate PL₀. Voltages can also be applied to data lines DL₀ through DL_{X} associated with memory cell group 202₀. The voltage on a particular data line of data lines DL₀ through DL_{X} associated with memory cell group 202₀ can have a value based on the value of information to be stored in a memory cell 202 coupled to that particular data line. In this example write operation, access line WL₁ through WLm of memory cell group 202₀ can be deactivated (unselected), such that memory cells 202 associated with access line WL₁ through WLm of memory cell group 202₀ are unselected memory cells (not selected to store information).

Storing information in memory cells 202 associated with access lines WL₁ through WLm of memory cell group 202₀ can be performed in ways similar to those of memory cells 202 associated with access line WL0 of memory cell group 202₀. In a write operation, access lines WL₀ through WLm of memory cell group 202₀ can be activated (selected) one at a time to store information in memory cells 202 associated with the selected access line.

To read information stored in memory cells 202 associated with access line WL0 of memory cell group 202₀, access line WL0 and data lines DL₀ through DL_{X} associated with memory cell group 202₀ can be activated to access (e.g., to select) memory cells 202 associated with access line WL0 of memory cell group 202₀. Driver 225₀ can be activated to apply a voltage to conductive plate PL₀. In this example read operation, the voltage on a particular data line of data lines DL₀ through DL_{X} associated with memory cell group 202₀ can have a value based on value of information stored in a memory cell 202 coupled to that particular data line. Sensing circuit 215 can operate to determine the value (e.g., logic “0” or logic “1”) of information stored in each memory cell 202 (selected memory cells) of memory cell group 202₀. In this example read operation, access lines WL₁ through WLm of memory cell group 202₀ can be deactivated (unselected), such that memory cells 202 associated with access lines WL₁ through WLm of memory cell group 202₀ are unselected memory cells (not selected to read information from them).

In FIG. 2A, transistors Tsel₀ through Tsel_{X} associated with different memory cell groups (different conductive plates) may not be concurrently (e.g., simultaneously) turned on. For example, in a read operation of reading memory cells 202 of memory cell group 202₀, transistors Tsel₀ through Tsel_{X} of memory cell group 202₀ are turned on. However, transistors Tsel₀ through Tsel_{X} associated with memory cell group 202₁ through memory cell group 202ᵢ are turned off. Thus, in a read operation, data lines DL₀ through DL_{X} associated with one memory cell group are coupled to sensing circuit 215 (through the turned-on transistors Tsel₀ through Tsel_{X}) and data lines DL₀ through DL_{X} associated with other memory groups are decoupled from (not coupled to) sensing circuit 215.

FIG. 2A shows an example of a short 222 coupled between conductive plates PL₀ and PL₁. Conductive plates PL₀ and PL₁ are adjacent each other (e.g., immediately next to each other). Short 222 is an unintended element (e.g., unintended conductive path (e.g., current path)) in memory device 200 that may be a result of a random defect introduced to memory device 200 during or after its fabrication. Short 222 may form a conductive path that can cause current to flow between conductive plate PL₀ and conductive plate PL₁. Short 222 can be identified (e.g., discovered) during testing of memory device 200 during or after fabrication of memory device 200. After short 222 is identified, one of conductive plate PL₀ and conductive plate PL₁ and associated circuit elements (e.g., memory cells 202) can be selected (e.g., designated) as a damaged portion (not used to store information). The other conductive plate and circuit elements (e.g., memory cells 202) can still be considered as a normal (undamaged) portion. In FIG. 2A for example, conductive plate PL₁ and its associated circuit elements (e.g., memory cells 202 in memory cell group 202₁) can be selected (e.g., designated) as a damaged portion. Thus, in this example, memory cells 202 in memory cell group 202₁ are not used to store information. In this example, conductive plate PL₀ and its associated circuit elements (e.g., memory cells 202 in memory cell group 202₀) can be considered as a normal portion. Thus, in this example, memory cells 202 in memory cell group 202₀ can still be used to store information.

In memory device 200 of FIG. 2A, one of conductive plates PL₀ through PLᵢ and its associated circuit elements (e.g., memory cells, data lines, access lines, and cell plate driver) can be selected to be a redundant portion of memory device 200. For example, conductive plate PLᵢ and its associated circuit elements can be a redundant portion. Thus, conductive plate PLᵢ can be called a redundant conductive plate. Memory device 200 can use the redundant portion to replace (e.g., repair) a damaged portion of memory device 200. The damaged portion can be a portion in a main memory array (e.g., regular memory array) of memory device 200. For example, conductive plates PL₀ through PLᵢ₋₁ and their associated circuit elements (e.g., memory cells, data lines, access lines, and cell plate drivers) can be included in a main memory array of memory device 200. In this example, conductive plate PLᵢ and its associated circuit elements (e.g., in the redundant memory array of memory device 200) can be used to replace the damaged portion (which includes conductive plate PL₀) in the main memory array.

Memory device 200 can be configured to replace memory operations (e.g., write and read operations) associated with a damaged portion (e.g., portion including conductive plate PL₁ in the above example) with operation associated with conductive plate (e.g., redundant conductive plate) PLᵢ. Memory control circuitry of memory device 200 (e.g., similar to memory control circuitry 110 of FIG. 1) can be configured (e.g., programed) to store address information (e.g., addresses of physical locations) of the memory cells (e.g., columns of memory cells 202) associated with the conductive plate of the damage portion. Then, based on the store address information, the memory control circuitry of memory device 200 can replace (e.g., by rerouting) memory operations (e.g., write and read operations) involving the memory cells associated with the conductive plate of the damaged portion with memory operations (e.g., write and read operations) of memory cells associated with the conductive plate of the redundant portion.

In the example described above, conductive plate PL₁ is selected (e.g., designated) to be the damaged conductive plate. In this example, memory operation (e.g., write or read operation) involving conductive plate PL₁ (damaged conductive plate) can be replaced (e.g., repaired) by memory operation (e.g., write or read operation) involving conductive plate PLᵢ and its associated circuit elements. For example, a write operation to store information in memory cells 202 associated with conductive plate PL₁ can be replaced with a write operation to memory cells 202 associated with conductive plate PLᵢ (e.g., redundant conductive plate). In another example, a read operation to read information from memory cells 202 associated with conductive plate PL₁ can be replaced with a read operation to read information from memory cells 202 associated with conductive PLᵢ. For example, during a read operation, memory device 200 may receive a read command to read information at addresses associated with memory cells 202 associated with conductive plate PL₁. In response to the read command, memory device 200 can perform a read operation to read information from memory cells associated with conductive plate PLᵢ (included in the redundant portion) instead of reading information from memory cells associated with conductive plate PL₁. Then, memory device 200 can provide the information read from memory cells associated with conductive plate PLᵢ to I/O circuitry of memory device 200.

In the above example where conductive plate PL₁ is selected (e.g., designated) to be the damaged conductive plate (due to short 222), conductive plate PL₀ and associated circuit elements (e.g., memory cell group 202₀) can be configured to operate in normal ways as a normal portion (undamaged portion) of memory device 200. Thus, conductive plate PL₀ and associated circuit elements (e.g., memory cell group 202₀) is not replaced by a redundant portion of memory device 200. Memory cells 202 of memory cell group 202₀ (associated with conductive plate PL₀) can be used to store information (in a write operation) by applying appropriate voltages to conductive plate PL₀ and data lines ld0-x associated with memory cell group 202₀.

Reading information from memory cell group 202₀ can be performed in a read operation using the following techniques. For example, in response to a read command to read information from memory cells 202 associated with access line WL0 of memory cell group 202₀, memory device 200 can activate access line WL0 and data lines DL₀ through DL_{X} associated with memory cell group 202₀ to access (e.g., to select) memory cells 202 associated with access line WL0 of memory cell group 202₀. Driver 225₀ can be activated (e.g., turned on) to apply a positive voltage to conductive plate PL₀. Driver 225₁ can be deactivated (e.g., turned off) to place conductive plate PL₁ in a float condition. Alternatively, driver 225₁ can be activated (e.g., turned on) to apply a positive voltage to conductive plate PL₀. The voltages applied to conductive plates PL₀ and PL₁ (by respective activated drivers 225₀ and 225₁) can be the same.

In the above read operation, signal SEL₀ can be activated (e.g., provided with a positive voltage) to turn on transistors Tsel₀ through Tsel_{X} associated with data lines DL₀ through DL_{X} in memory cell group 202₀. The turned-on transistors Tsel₀ through Tsel_{X} couple data lines (selected data lines) DL₀ through DL_{X} in memory cell group 202₀ to sensing circuit 215. In this example, signals SEL₁ through SELᵢ can be deactivated. Thus, transistors Tsel₀ through Tsel_{X} of associated memory cell groups 202₁ through 202ᵢ are not turned on. Therefore, data lines (unselected data lines) DL₀ through DL_{X} of associated memory cell groups 202₁ through 202ᵢ are not coupled to sensing circuit 215 in this example. In an example, the unselected data lines (e.g., data lines DL₀ through DL_{X} associated memory cell groups 202₁ through 202ᵢ) can be coupled to ground potential (e.g., voltage Vss). Since data lines DL₀ through DL_{X} associated memory cell groups 202₁ are not coupled to sensing circuit 215, information (if any) stored in memory cells 202 of memory cell group 202₁ are ignored (e.g., not sensed by sensing circuit 215).

As described above, data lines DL₀ through DL_{X} associated with selected memory cells of memory cell group 202₀ are coupled to sensing circuit 215. Sensing circuit 215 can operate to determine the value (e.g., logic “0” or logic “1”) of information stored in each memory cell 202 (selected memory cells) of memory cell group 202₀ based on the signals (e.g., voltage values).

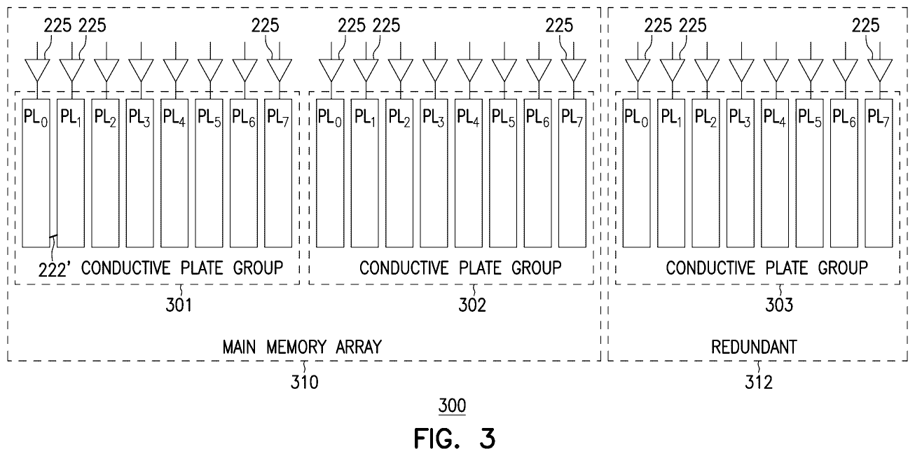

FIG. 3 shows a memory device 300 including conductive plate groups 301, 302, and 303, according to some embodiments described herein. As shown in FIG. 3, each of conductive plate groups 301, 302, and 303 can include conductive plates PL₀ through PL₁ adjacent each other. FIG. 3 shows three conductive plate groups 301, 302, and 303 as an example. However, memory device 300 can have more than three conductive plate groups. FIG. 3 shows an example where each of conductive plate groups 301, 302, and 303 includes eight conductive plates PL₀ through PL₇. However, the number of conductive plates of conductive plate groups 301, 302, and 303 can be different from eight.

In FIG. 3, each of conductive plates PL₀ through PL₇ can be associated with circuit elements including memory cells, data lines, access lines, and a sensing circuit like memory cells 202, data lines DL₀ through DL_{X}, access lines WL₀ through WLm, and sensing circuit 215, respectively, of FIG. 2A. For simplicity, some of such circuit elements are not shown in FIG. 3.

As shown in FIG. 3, memory device 300 can include drivers (driver circuits) 225, each of which can be similar to or the same as one of drivers 225₀ through 225ᵢ of FIG. 2A. As shown in FIG. 3, drivers 225 can be associated with conductive plates groups 301, 302, and 303 in a one-to-one configuration. Thus, the number of drivers 225 can be equal to the number of conductive plate groups 301, 302, and 303. In the example of FIG. 3, the number of drivers 225 is 24 which is the same as the number (24) of conductive plates of conductive plate groups 301, 302, and 303. A driver 225 may not be shared by conductive plates PL₀ through PL₇ of the same conductive plate group or conductive plates PL₀ through PL₇ of different conductive plate groups. Each driver 225 can be used to apply a voltage to a respective conductive plate.

FIG. 3 shows an example of a short 222′, which can be similar to or the same as short 222 of FIG. 2A. As shown in FIG. 3, short 222′ is coupled between conductive plates PL₀ and plate PL₁ (adjacent conductive plates). Thus, in the example of FIG. 3, conductive plates PL₀ and PL₁ are coupled to each other (e.g., electrically in contact with each other) through short 222′. Short 222′ can cause damage to a portion of memory device 300 that includes conductive plates PL₀ and PL₁ and their associated circuit elements. In the example of FIG. 3, conductive plate PL₁ can be selected (e.g., designated) to be a damaged conductive plate (like conductive plate PL₁ of FIG. 2A).

In memory device 300, conductive plate group 303 and its associated circuit elements (e.g., memory cells, data lines, access lines, and cell plate drivers) can be included in a redundant portion (e.g., redundant (spare) memory array portion) 312 of memory device 300. Conductive plate group 303 and its associated circuit elements can be used to replace (e.g., repair) a damaged portion in main memory array 310 of memory device 300. In the example of FIG. 3, conductive plate PL₁ and its associated circuit elements in redundant portion 312 can be used to replace conductive plate PL₁ and its associated circuit elements in main memory array 310.

As shown in FIG. 3, conductive plate group 303 of redundant portion 312 can have the same number of conductive plates (e.g., eight conductive plates PL₀ through PL₇) as each of conductive plate groups 301 and 302 included in main memory portion 310. Conductive plate groups 301, 302, and 303 can be organized in the same pattern from conductive plate PL₀ through PL₇. Relative physical locations (and addresses) of conductive plates PL₀ through PL₇ (and associated circuit elements) of a conductive plate group (e.g., conductive plate group 301) in memory portion 310 can be the same as relative physical locations (and addresses) of conductive plates PL₀ through PL₇ (and associated circuit elements) of a conductive plate group (e.g., conductive plate group 303) in redundant portion 312. The relative physical locations and addresses can simplify memory operations (e.g., write and read operations) associated with replacing a damaged portion in memory portion 310. For example, in the example of FIG. 3, since conductive plate PL₁ and its associated circuit elements are designated as a damaged portion, conductive plate PL₁ and its associated circuit elements in redundant portion 312 can be used as a replacement portion.

In a write operation intended to store information in memory cells (not shown in FIG. 3) associated with conductive plate PL₁ of conductive plate group 301, memory device 300 can operate to store the information in memory cells (not shown in FIG. 3) associated with conductive plate PL₁ in redundant portion 312 instead of the memory cells associated with conductive plate PL₁ in conductive plate group 301 because conductive plate PL₁ of conductive plate group 301 is damaged. Thus, in a read operation intended to read information from memory cells associated with conductive plate PL₁ of conductive plate group 301, memory device 300 can operate to read information from memory cells associated with conductive plate PL₁ in redundant portion 312 instead of the memory cells associated with conductive plate PL₁ of conductive plate group 301.

Write and read operations of memory cells (not shown) associated with conductive plate PL₁ of conductive plate group 301 can be similar to the write and read operations of memory cells 202 associated with conductive plate PL₁ of memory cell group 202₀ of FIG. 2A.

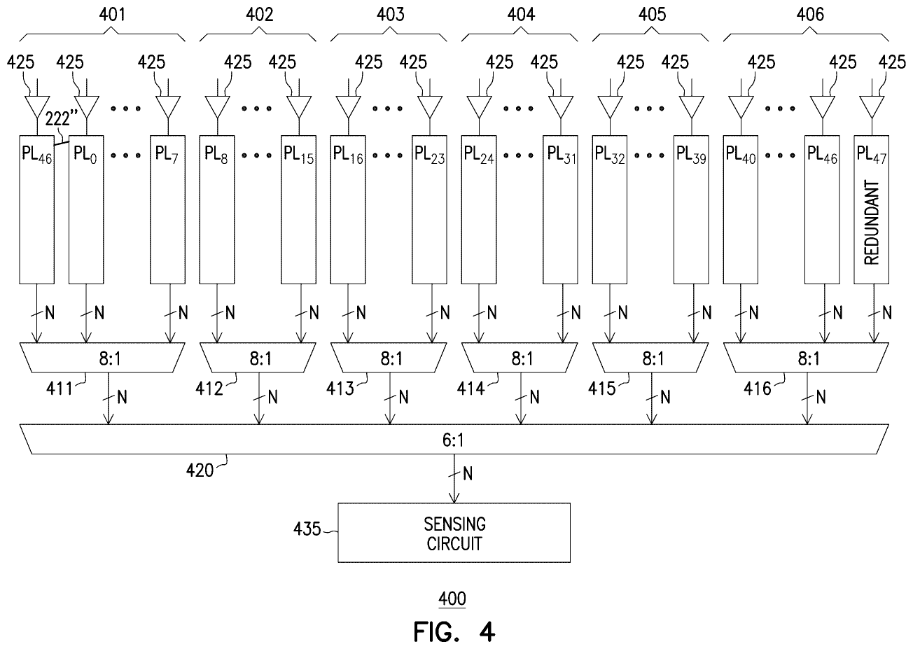

FIG. 4 shows a memory device 400 including conductive plate groups 401 through 406, multiplexers 411 through 416, and multiplexer 420, according to some embodiments described herein. FIG. 4 shows an example where the number of conductive plate groups 401 through 406 is six and the number of multiplexers 411 through 416 is also six. However, the numbers of conductive plate groups and associated multiplexers can vary. FIG. 4 shows an example where each conductive plate group includes eight conductive plates. However, the number of conductive plates in each conductive plate group can vary. In the example of FIG. 4, memory device 400 can include a total of 48 conductive plates from conductive plates PL₀ through PL₄₇ (six conductive plate groups and eight conductive plates in each conductive plate group). Each of conductive plates PL₀ through PL₄₇ can include associated circuit elements (e.g., memory cells, data lines, access lines, and cell plate driver) like each conductive plate (e.g., conductive plate PL₀) of FIG. 2A.

Memory device 400 can include a redundant portion 412, which can include conductive plate PL₄₇ and associated circuit elements (e.g., memory cells and data lines, access lines, and cell plate driver). Thus, conductive plate PL₄₇ can be called a redundant conductive plate. Redundant portion 412 can be used to replace a damaged portion that may be caused by a short (e.g., like short 222 in FIG. 2A) in the conductive plates of memory device 400.

As shown in FIG. 4, each conductive plate is associated with a group of N data lines (where N is an integer) that are parallel data lines (N parallel data lines). A group of N data lines is similar to a group of data lines DL₀ through DL_{X} of FIG. 2A.

In FIG. 4, each of multiplexers 411 through 416 is associated with one of conductive plate groups 401 through 406. Each of multiplexers 411 through 416 can be a P:1 multiplexer where P represents (is equal to) the number of conductive plates in a conductive plate group. FIG. 4 shows an example where each of multiplexers 411 through 416 is an 8:1 multiplexer because the number of conductive plates (e.g., conductive plates PL₀ through PL₇) in a conductive plate group is eight (e.g., P=8). Each of multiplexers 411 through 416 can include an input (e.g., input nodes) coupled to the group of N data lines associated with each conductive plate of a respective conductive plate group. Each of multiplexers 411 through 416 can include an output (e.g., output nodes) that can include a group of N conductive lines (N parallel data lines). During a read operation, each of multiplexers 411 through 416 can select information from a particular group of N data lines (among eight groups of N data lines) at its input (multiplexer input or MUX input). Then, each of multiplexers 411 through 416 can pass the information (selected information) to its output (multiplexer output or MUX output). The particular group of N data lines are associated with a selected conductive plate (e.g., PL₀) among conductive plates (e.g., conductive plates PL₀ through PL₇) of a conductive plate group (e.g., conductive plate group 401). The selected conductive plate (e.g., conductive plate PL₀) is associated with selected memory cells during a memory operation (e.g., read operation) of memory device 400.

Multiplexer 420 can include an input (e.g., input nodes) coupled to the group of N conductive lines at the output of multiplexers 411 through 416 can be coupled to the input of multiplexer 420. Multiplexer 420 can include an output (e.g., output nodes) that can include a group of N conductive lines (N parallel conductive lines). Multiplexer 420 can be a M:1 multiplexer where M represents (is equal to) the number of conductive plate groups. FIG. 4 shows an example where multiplexer 420 is a 6:1 multiplexer because the number of conductive plate groups (e.g., conductive plate group 401 through 406) is six (e.g., M=6). Multiplexer 420 can operate to select information from a particular group of N conductive lines (among six groups of N conductive lines) at its input and pass the information to its output.

Memory device 400 can include a sensing circuit 435 coupled to the N conductive lines at the output of multiplexer 420. Sensing circuit 435 can operate to determine the value (e.g., logic “0” or logic “1”) of information read from memory cells associated with a conductive plate among conductive plates PL₀ through PL₄₇.

Memory device 400 can perform a read operation similar to that of memory device 200 or 300 to read information from memory cells associated with conductive plates PL₀ through PL₄₇. FIG. 4 shows an example of a short 222″ between conductive plates PL₀ and PL₁. However, if short 222″ does not exist in memory device 400, then memory device 400 can read information directly from selected memory cells associated with conductive plates PL₀ through PL₄₆.

In the example of FIG. 4, in the presence of short 222″, memory device 400 can read information in ways similar to those described above with reference to FIG. 2A and FIG. 3. For example, if memory device 400 has a short between conductive plates PL₀ and PL₁, then conductive plate PL₁ and associated circuit elements can by selected (e.g., designated) as a damaged portion. In this example, conductive plate PL₄₇ and its associated circuit elements (e.g., memory cells) can be used to replace conductive plate PL₁ and its associated circuit elements (e.g., memory cells). In this example, reading information from memory cells associated with conductive plates PL₀ and PL₁ can be similar to reading information from memory cells associated with conductive plates PL₀ and PL₁ of memory device 200 of FIG. 2A.

The techniques described above can improve yield and reduce cost associated with fabrication of the memory device (e.g., memory devices 100, 200, 300, and 400) described herein. Further, the structures and configurations of the memory device (e.g., memory devices 100, 200, 300, and 400) described herein allow proper memory operations (e.g., read and write operations) described above that may be impractical for some conventional memory devices.

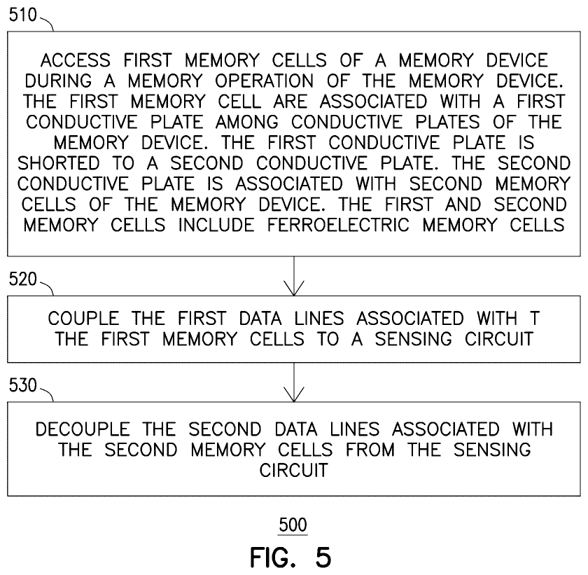

FIG. 5 is a flowchart of an example method 500 for operating a memory device, according to some embodiments described herein. Method 500 can be performed by an apparatus (e.g., memory device 100, 200, or 300) and/or system (e.g., system 600 in FIG. 6). As shown in FIG. 5, method 500 can include activities (e.g., operations) 510, 520, and 530.

Activity 510 can include accessing first memory cells of a memory device during a memory operation of the memory device. The first memory cells are associated with a first conductive plate among conductive plates of the memory device. The first conductive plate is shorted to a second conductive plate of the conductive plates. The second conductive plate is associated with second memory cells of the memory device. The first and second memory cells include ferroelectric memory cells.

Activity 520 can include coupling first data lines associated with the first memory cells to a sensing circuit during the memory operation.

Activity 530 can include decoupling second data lines associated with the second memory cells from the sensing circuit during the memory operation.

Method 500 described above can include fewer or more activities relative to activities 510, 520, and 530 shown in FIG. 5. For example, method 500 can include additional activities (e.g., operations) associated with the apparatuses (e.g., memory devices 100, 200, 300, and 400) and/or system (e.g., system 600 in FIG. 6). As an example, method 500 can additional activities (e.g., operations) described above with reference to FIG. 2A through FIG. 3. Method 500 can provide improvements and benefits similar to those of memory devices (e.g., memory devices 100, 200, 300, and 400) described above.

FIG. 6 shows an apparatus in the form of a system (e.g., electronic system) 600, according to some embodiments described herein. System 600 can be viewed as a machine. System (e.g., machine) 600 can include or be included in a computer, a cellular phone, or other electronic systems. As shown in FIG. 6, system 600 can include components (e.g., devices) located on a circuit board (e.g., PCB) 602. The components can include a processor (e.g., a hardware processor) 615, a memory device 620, a memory module (e.g., DRAM module) 601, a memory controller 630, a graphics controller 640, an I/O controller 650, a display 652, a keyboard 654, a pointing device 656, at least one antenna 658, a storage device 660, and a bus 670. Bus 670 can include conductive lines (e.g., metal-based traces on a circuit board 602 where the components of system 600 are located).

System 600 may be configured to perform one or more of the methods and/or operations described herein. At least one of the components of system 600 (e.g., at least one of processor 615, memory device 620, memory controller 630, graphics controller 640, and I/O controller 650) can include at least one of the devices described herein. For example, memory device 620 can include one of memory devices 100, 200, 300, and 400.

In FIG. 6, processor 615 can include a general-purpose processor or an application specific integrated circuit (ASIC). Processor 615 can include a central processing unit (CPU) and processing circuitry. Graphics controller 640 can include a graphics processing unit (GPU) and processing circuitry. Memory device 620 can include a FeRAM device, a DRAM device, a static random-access memory (SRAM) device, a flash memory device, phase change memory, or a combination of these memory devices, or other types of memory. FIG. 6 shows an example where memory device 620 is a stand-alone memory device separated from processor 615. In an alternative structure, memory device 620 and processor 615 can be located on the same IC chip (e.g., a semiconductor die or IC die). In such an alternative structure, memory device 620 is an embedded memory in processor 615, such as embedded DRAM (eDRAM), embedded SRAM (eSRAM), embedded flash memory, or another type of embedded memory.

Storage device 660 can include a drive unit (e.g., hard disk drive (HHD), solid-state drive (SSD), or another mass storage device). Storage device 660 can include a machine-readable medium 662 and processing circuitry. Machine-readable medium 662 can store one or more sets of data structures or instructions 664 (e.g., software) embodying or used by any one or more of the techniques or functions described herein. Instructions 664 may also reside, completely or at least partially, within memory device 620, memory controller 630, processor 615, or graphics controller 640 during execution thereof by system (e.g., machine) 600.

In an example, one of (or any combination of) processor 615, memory device 620, memory controller 630, graphics controller 640, and storage device 660 may constitute machine-readable media. Non-limiting machine-readable medium examples may include solid-state memories and optical and magnetic media. Specific examples of machine-readable media may include non-volatile memory, such as semiconductor memory devices (e.g., EPROM or EEPROM) and flash memory devices; magnetic disks, such as internal hard disks and removable disks; magneto-optical disks; RAM; and CD-ROM and DVD-ROM disks.

FIG. 6 shows machine-readable medium 662 as a single medium as an example. However, the term “machine-readable medium” may include a single medium or multiple media (e.g., a centralized or distributed database, and/or associated caches and servers) configured to store instructions 664. Further, the term “machine-readable medium” may include any medium that is capable of storing, encoding, or carrying instructions for execution by system 600 and that causes system 600 to perform any one or more of the techniques of the present disclosure, or that is capable of storing, encoding or carrying data structures used by or associated with such instructions. In some examples, machine-readable media may include non-transitory machine-readable media. In some examples, machine-readable media may include machine-readable media that is not a transitory propagating signal.

Display 652 can include a liquid crystal display (LCD), a touchscreen (e.g., capacitive or resistive touchscreen), or another type of display. Pointing device 656 can include a mouse, a stylus, or another type of pointing device. In some structures, system 600 does not have to include a display. Thus, in such structures, display 652 can be omitted from system 600.

Antenna 658 can include one or more directional or omnidirectional antennas, including, for example, dipole antennas, monopole antennas, patch antennas, loop antennas, microstrip antennas, or other types of antennas suitable for transmission of radio frequency (RF) signals. In some structures, system 600 does not have to include an antenna. Thus, in such structures, antenna 658 can be omitted from system 600.

I/O controller 650 can include a communication module for wired or wireless communication (e.g., communication through one or more antennas 658). Such wireless communication may include communication in accordance with WiFi communication technique, Long Term Evolution Advanced (LTE-A) communication technique, Fifth Generation (5G) wireless system or variations or derivatives, 6G mobile networks system or variations or derivatives, 6G New Radio (NR) system or variations or derivatives, or other cellular service standards, or other communication techniques.

I/O controller 650 can also include a module to allow system 600 to communicate with other devices or systems in accordance with to one or more of the following standards or specifications (e.g., I/O standards or specifications), including Universal Serial Bus (USB), DisplayPort (DP), High-Definition Multimedia Interface (HDMI), Thunderbolt, Peripheral Component Interconnect Express (PCIe), Ethernet, and other specifications.

Connector 655 can include terminals (e.g., pins) to allow system 600 to receive a connection (e.g., an electrical connection) from an external device (or system). This may allow system 600 to communicate (e.g., exchange information) with such a device (or system) through connector 655. Connector 655 and at least a portion of bus 670 can include conductive lines that conform with at least one of USB, DP, HDMI, Thunderbolt, PCIe, Ethernet, and other specifications.

FIG. 6 shows the components (e.g., devices) of system 600 arranged separately from each other as an example. For example, each of processor 615, memory device 620, memory controller 630, graphics controller 640, and I/O controller 650 can be included in (e.g., formed in or formed on) a separate integrated circuit (IC) chip (e.g., separate semiconductor die or separate IC die). In some structures of system 600, two or more components (e.g., processor 615, memory device 620, graphics controller 640, and I/O controller 650) of system 600 can be included in (e.g., formed in or formed on) the same IC chip (e.g., same semiconductor die), forming a SoC, or alternatively, a SiP.

The illustrations of the apparatuses (e.g., memory devices 100, 200, 300, and 400, and system 600) described above are intended to provide a general understanding of the structure of different embodiments and are not intended to provide a complete description of all the elements and features of an apparatus that might make use of the structures described herein.

Any of the components described above with reference to FIG. 1 through FIG. 6 can be implemented in a number of ways, including simulation via software. Thus, apparatuses (e.g., memory devices 100, 200, 300, and 400, and system 600) may all be characterized as “modules” (or “module”) herein. Such modules may include hardware circuitry, single- and/or multi-processor circuits, memory circuits, software program modules and objects and/or firmware, and combinations thereof, as desired and/or as appropriate for particular implementations of various embodiments. For example, such modules may be included in a system operation simulation package, such as a software electrical signal simulation package, a power usage and ranges simulation package, a capacitance-inductance simulation package, a power/heat dissipation simulation package, a signal transmission-reception simulation package, and/or a combination of software and hardware used to operate or simulate the operation of various potential embodiments.

The apparatuses and methods described above can include or be included in high-speed computers, communication and signal processing circuitry, single- or multi-processor modules, single or multiple embedded processors, multicore processors, message information switches, and application-specific modules including multilayer, multichip modules. Such apparatuses may further be included as subcomponents within a variety of other apparatuses (e.g., electronic systems), such as televisions, cellular telephones, personal computers (e.g., laptop computers, desktop computers, handheld computers, tablet computers, etc.), workstations, radios, video players, audio players (e.g., MP3 (Motion Picture Experts Group, Audio Layer 3) players), vehicles, medical devices (e.g., heart monitor, blood pressure monitor, etc.), set top boxes, and others.

The illustrations of apparatuses (e.g., memory devices 100, 200, 300, and 400, and system 600) and methods (e.g., method 500 and methods of operating memory devices 100, 200, 300, and 400, and system 600) are intended to provide a general understanding of the structure of various embodiments and are not intended to provide a complete description of all the elements and features of apparatuses that might make use of the structures described herein. An apparatus herein refers to, for example, either a device (e.g., any of memory devices 100, 200, 300, and 400) or a system (e.g., an electronic item that can include any of memory devices 100, 200, 300, and 400, and system 600).

Any of the components described above with reference to FIG. 1 through FIG. 6 can be implemented in a number of ways, including simulation via software. Thus, apparatuses (e.g., memory devices 100, 200, 300, and 400, and system 600), or part of each of these memory devices described above, may all be characterized as “modules” (or “module”) herein. Such modules may include hardware circuitry, single- and/or multi-processor circuits, memory circuits, software program modules and objects and/or firmware, and combinations thereof, as desired and/or as appropriate for particular implementations of various embodiments. For example, such modules may be included in a system operation simulation package, such as a software electrical signal simulation package, a power usage and ranges simulation package, a capacitance-inductance simulation package, a power/heat dissipation simulation package, a signal transmission-reception simulation package, and/or a combination of software and hardware used to operate or simulate the operation of various potential embodiments.

The memory devices (e.g., memory devices 100, 200, 300, and 400, and system 600) described herein may be included in apparatuses (e.g., electronic circuitry) such as high-speed computers, communication and signal processing circuitry, single- or multi-processor modules, single or multiple embedded processors, multicore processors, message information switches, and application-specific modules including multilayer, multichip modules. Such apparatuses may further be included as subcomponents within a variety of other apparatuses (e.g., electronic systems), such as televisions, cellular telephones, personal computers (e.g., laptop computers, desktop computers, handheld computers, tablet computers, etc.), workstations, radios, video players, audio players (e.g., MP3 (Motion Picture Experts Group, Audio Layer 3) players), vehicles, medical devices (e.g., heart monitor, blood pressure monitor, etc.), set top boxes, and others.

The embodiments described above with reference to FIG. 1 through FIG. 6 include apparatuses and methods of operating the apparatuses. One of the apparatuses includes conductive plates adjacent each other; memory cells associated with the conductive plates; drivers coupled to the conductive plates such that one of the drivers is associated with one of the conductive plates; and a short coupled between a first conductive plate of the conductive plate and a second conductive plate of the conductive plates. Other embodiments, including additional apparatuses and methods, are described.

In the detailed description and the claims, the term “on” used with respect to two or more elements (e.g., materials), one “on” the other, means at least some contact between the elements (e.g., between the materials). The term “over” means the elements (e.g., materials) are in close proximity, but possibly with one or more additional intervening elements (e.g., materials) such that contact is possible but not required. Neither “on” nor “over” implies any directionality as used herein unless stated as such.

In the detailed description and the claims, a list of items joined by the term “at least one of” can mean any combination of the listed items. For example, if items A and B are listed, then the phrase “at least one of A and B” means A only; B only; or A and B. In another example, if items A, B, and C are listed, then the phrase “at least one of A, B, and C” means A only; B only; C only; A and B (excluding C); A and C (excluding B); B and C (excluding A); or all of A, B, and C. Item A can include a single element or multiple elements. Item B can include a single element or multiple elements. Item C can include a single element or multiple elements.

In the detailed description and the claims, a list of items joined by the term “one of” can mean only one of the list items. For example, if items A and B are listed, then the phrase “one of A and B” means A only (excluding B), or B only (excluding A). In another example, if items A, B, and C are listed, then the phrase “one of A, B, and C” means A only; B only; or C only. Item A can include a single element or multiple elements. Item B can include a single element or multiple elements. Item C can include a single element or multiple elements.

In the detailed description and the claims, the terms “first,” “second,” and “third,” etc. are used merely as labels, and are not intended to impose numerical requirements on their objects.

The above description and the drawings illustrate some embodiments of the inventive subject matter to enable those skilled in the art to practice the embodiments of the inventive subject matter. Other embodiments may incorporate structural, logical, electrical, process, and other changes. Examples merely typify possible variations. Portions and features of some embodiments may be included in, or substituted for, those of others. Many other embodiments will be apparent to those of skill in the art upon reading and understanding the above description.

What is claimed is:

1. An apparatus comprising:
conductive plates adjacent each other;
memory cells associated with the conductive plates;
drivers coupled to the conductive plates such that one of the drivers is associated with one of the conductive plates; and
a short coupled between a first conductive plate of the conductive plates and a second conductive plate of the conductive plates.

2. The apparatus of claim 1, wherein the memory cells include ferroelectric memory cells, and the conductive plates forming part of memory elements of the memory cells.

3. The apparatus of claim 1, wherein the conductive plates are organized into conductive plate groups, each of the conductive plate groups including more than two of the conductive plates.

4. The apparatus of claim 3, further comprising:
first data lines associated with the first conductive plate; and
second data lines associated with the second conductive plate.

5. The apparatus of claim 1, wherein one of the conductive plates is configured to replace the second conductive plate.

6. The apparatus of claim 1, wherein the conductive plates are organized into conductive plate groups, each of the conductive plate groups including more than two of the conductive plates, and a conductive plate of one of the conductive plate groups is configured to replace the second conductive plate.

7. The apparatus of claim 1, further comprising control circuitry to:
activate a first driver of the drivers during a memory operation, wherein the first driver is coupled to the first conductive plate; and
deactivate a second driver of the drivers during the memory operation, wherein the second driver is coupled to the second conductive plate.

8. The apparatus of claim 1, further comprising control circuitry to:
couple data lines associated with the first conductive plate to a sensing circuit during a memory operation; and
decouple data lines associated with the second conductive plate from the sensing circuit during the memory operation.

9. The apparatus of claim 1, wherein the first conductive plate is adjacent the second conductive plate.

10. An apparatus comprising:
conductive plate groups, each of the conductive plate groups including a number of conductive plates, the number of conductive plates being greater than two;
data lines associated with each of the conductive plates of each of the conductive plate groups;
memory cells associated with the data lines;
a short coupled between a first conductive plate and a second conductive plate of one of the conductive plate groups;
first multiplexers, each of the first multiplexers associated with a respective conductive plate group of the conductive plate groups and including inputs coupled to the data lines associated with each of the conductive plates of the respective conductive plate group;
a second multiplexer including inputs coupled to outputs of the first multiplexers; and
a sensing circuit coupled to outputs of the second multiplexer.

11. The apparatus of claim 10, wherein one of the conductive plates is a redundant conductive plate.

12. The apparatus of claim 10, wherein each of the first multiplexers is a P:1 multiplexer, and P represents a number of conductive plates in each of the conductive plate groups.

13. The apparatus of claim 12, wherein the second multiplexer is an M:1 multiplexer, and M represents a number of the conductive plate groups.

14. The apparatus of claim 10, further comprising a number of drivers coupled to the number of conductive plates in each of the conductive plate groups, wherein the number of drivers is equal to a total number of conductive plates of the conductive plate groups.

15. The apparatus of claim 10, wherein each of the memory cells includes a ferroelectric capacitor coupled to a conductive plate of the number of conductive plates in one of the conductive plate groups.

16. A method comprising:
accessing first memory cells of a memory device during a memory operation of the memory device, the first memory cells associated with a first conductive plate among conductive plates of the memory device, the first conductive plate shorted to a second conductive plate of the conductive plates, the second conductive plate associated with second memory cells of the memory device, and the first and second memory cells including ferroelectric memory cells;
coupling first data lines associated with the first memory cells to a sensing circuit during the memory operation; and
decoupling second data lines associated with the second memory cells from the sensing circuit during the memory operation.

17. The method of claim 16, further comprise comprising:
activating, during the memory operation, a first driver coupled to the first conductive plate; and
deactivating, during the memory operation, a second driver coupled to the second conductive plate.

18. The method of claim 16, further comprise comprising:
activating, during the memory operation, a first driver coupled to the first conductive plate; and
activating, during the memory operation, a second driver coupled to the second conductive plate.

19. The method of claim 16, wherein:
coupling the first data lines includes turning on, during the memory operation, first transistors coupled between a sensing circuit and the first data lines associated with the first memory cells; and
decoupling the second data lines includes turning off, during the memory operation, second transistors coupled between the sensing circuit and the second data lines associated with the second memory cells.

20. The method of claim 16, further comprising:
receiving a command to read information at addresses associated with the second memory cells; and
reading information from third memory cells in response to the command and the addresses, the third memory cells associated with a third conductive plate among conductive plates of the memory device.
